(19) United States
(12) Patent Application Publication
(10) Pub. No.: US 2020/0105977 A1
(43) Pub. Date: Apr. 2, 2020

(54) LIGHT-EMITTING UNIT

(71) Applicants: LITE-ON OPTO TECHNOLOGY (CHANGZHOU) CO., LTD., Changzhou City (CN); LITE-ON TECHNOLOGY CORPORATION, Taipei City (TW)

(72) Inventors: HONG-ZHI GU, New Taipei City (TW); KUO-MING CHIU, New Taipei City (TW)

(21) Appl. No.: 16/584,009

(22) Filed: Sep. 26, 2019

(30) Foreign Application Priority Data
Sep. 28, 2018 (CN) 201811139299.3

(51) Int. Cl. H01L 33/48; H01L 33/58

(52) U.S. Cl. CPC H01L 33/483; H01L 33/58

(57) ABSTRACT

A light-emitting unit includes a substrate, an optical lens, and a light-emitting chip. The substrate has a surrounding groove and a retaining structure located in the surrounding groove. The optical lens is disposed on the substrate and has a concavity and an auxiliary retaining member, and the auxiliary retaining member has a retaining groove. The auxiliary retaining member is engaged in the surrounding groove, and the retaining structure is engaged in the retaining groove. The light-emitting chip is disposed on the substrate and located in the concavity. A reserved space is formed between the retaining structure and the retaining groove.

### CROSS-REFERENCE TO RELATED PATENT APPLICATION

This application claims the benefit of priority to China Patent Application No. 201811139299.3, filed on Sep. 28, 2018 in People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a light-emitting unit, and more particularly to a light-emitting unit having a lens.

### BACKGROUND OF THE DISCLOSURE

For conventional light-emitting device that has a light-emitting diode and a lens, any slight misalignment between the lens and the light-emitting diode during assembly may result in an unexpected lighting pattern generated by the light-emitting device. It has become an important issue in the industry to accurately position the lens and the light-emitting diode when manufacturing the light-emitting device.

### SUMMARY OF THE DISCLOSURE

In response to the above-referenced technical inadequacies, the present disclosure provides a light-emitting unit for preventing a lens and a light-emitting diode from being in misalignment with each other during assembly, thereby preventing the light-emitting unit from generating an unexpected lighting pattern.

In one aspect, the present disclosure provides a light-emitting unit, which includes: a substrate, an optical lens, and a light-emitting chip. The substrate has a surrounding groove and a retaining structure located in the surrounding groove. The optical lens is disposed on the substrate and has a concavity and an auxiliary retaining member. The auxiliary retaining member has a retaining groove, and the auxiliary retaining member is engaged in the surrounding groove, and the retaining structure is engaged in the retaining groove. The light-emitting chip is disposed on the substrate and located in the concavity. A reserved space is formed between the retaining structure and the retaining groove.

In certain embodiments, the light-emitting chip is disposed on a supporting surface of the substrate, and a top surface of the retaining groove is flush with or is lower than the supporting surface.

In certain embodiments, the light-emitting unit further includes an auxiliary lens, the auxiliary lens is disposed on the substrate and located in the concavity. The auxiliary lens has an accommodating groove, and the light-emitting chip is located in the accommodating groove.

In certain embodiments, the light-emitting unit further includes a cured adhesive to adhere the retaining structure to the wall surface of the retaining groove, and a portion of the cured adhesive can be accommodated in the reserved space.

In certain embodiments, the auxiliary retaining member and the optical lens are integrally formed with each other.

In certain embodiments, the retaining structure has a lower end portion and an upper end portion, and the lower end portion is formed at a bottom of the surrounding groove, and the upper end portion is formed at one end of the lower end portion away from the bottom of the surrounding groove.

In certain embodiments, a maximum width of the lower end portion is smaller than a width of the surrounding groove, and a maximum width of the upper end portion is smaller than a minimum width of the lower end portion.

In certain embodiments, the retaining groove has a first groove section and a second groove section, the lower end portion is accommodated in the first groove section, and the upper end portion is accommodated in the second groove section.

In certain embodiments, the reserved space is formed between the second groove section and the upper end portion.

In certain embodiments, a ratio of a width of the surrounding groove to a width of the auxiliary retaining element is between 1:0.95 and 1:1.

In certain embodiments, a ratio of a depth of the surrounding groove to a length of the auxiliary retaining element is between 1:0.5 and 1:0.95.

In one aspect, the present disclosure provides a light-emitting unit, which includes: a substrate, an optical lens, and a light-emitting chip. The substrate has a retaining groove, the retaining groove is in the form of a ring, and the retaining groove has a first groove section and a second groove section. The optical lens is disposed on the substrate and has a concavity and a retaining structure. The retaining structure is fittingly engaged in the retaining groove, and the retaining structure has a lower end portion and an upper end portion. The lower end portion extends outwardly from one side of the substrate facing the optical lens, and the upper end portion extends outwardly from the lower end portion. The lower end portion is accommodated in the first groove section and the upper end portion is accommodated in the second groove section. The light-emitting chip is disposed on the substrate and located in the concavity. A reserved space is formed between the second groove section and the upper end portion.

In certain embodiments, the light-emitting unit further includes an auxiliary lens disposed on the substrate and located in the concavity. The auxiliary lens has an accommodating groove, and the light-emitting chip is located in the accommodating groove.

In certain embodiments, the light-emitting unit further includes a cured adhesive to adhere the retaining structure to the wall surface forming the retaining groove, and a portion of the cured adhesive is accommodated in the reserved space.

In certain embodiments, the retaining structure and the optical lens are integrally formed with each other.

In certain embodiments, the maximum width of the lower end portion is smaller than the width of the retaining groove, and the maximum width of the upper end portion is smaller than the minimum width of the lower end portion.

Therefore, one of the advantages of the present disclosure is that, the optical lens can be correctly disposed on a predetermined position of the substrate by the cooperation of the surrounding groove, the retaining structure and the retaining groove. Accordingly, the light-emitting unit can emit a predetermined lighting pattern, and the production yield of the light-emitting unit can be improved.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a perspective view of a light-emitting unit of the present disclosure.

FIG. 2 is a perspective exploded view of the light-emitting unit according to a first embodiment of the present disclosure.

FIG. 3 is a sectional exploded view of the light-emitting unit according to the first embodiment of the present disclosure.

FIG. 4 is a sectional assembled view of the light-emitting unit according to the first embodiment of the present disclosure.

FIG. 5 is a perspective exploded view of the light-emitting unit according to a second embodiment of the present disclosure.

FIG. 6 is a sectional exploded view of the light-emitting unit according to the second embodiment of the present disclosure.

FIG. 7 is a sectional assembled view of the light-emitting unit according to the second embodiment of the present disclosure.

FIG. 8 is a partially enlarged schematic view of FIG. 7.

FIG. 9 is a sectional assembled view of the light-emitting unit according to a third embodiment of the present disclosure.

FIG. 10 is a sectional assembled view of the assembly of the light-emitting unit according to a fourth embodiment of the present disclosure.

FIG. 11 is a perspective exploded view of the light-emitting unit according to a fifth embodiment of the present disclosure.

FIG. 12 is a sectional exploded view of the light-emitting unit according to the fifth embodiment of the present disclosure.

FIG. 13 is a sectional assembled view of the assembly of the light-emitting unit according to the fifth embodiment of the present disclosure.

FIG. 14 is a sectional assembled view of the assembly of the light-emitting unit according to a sixth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be disposed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

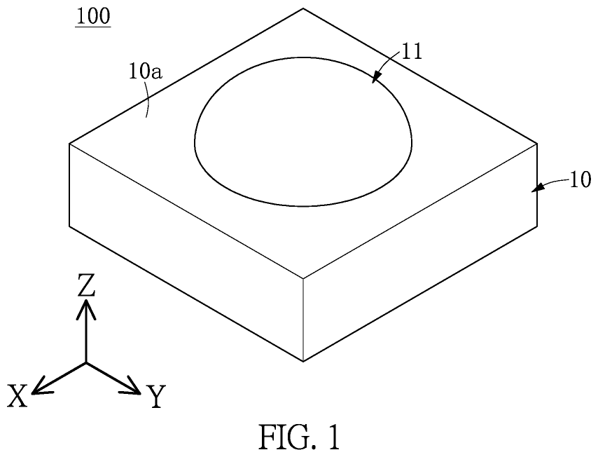

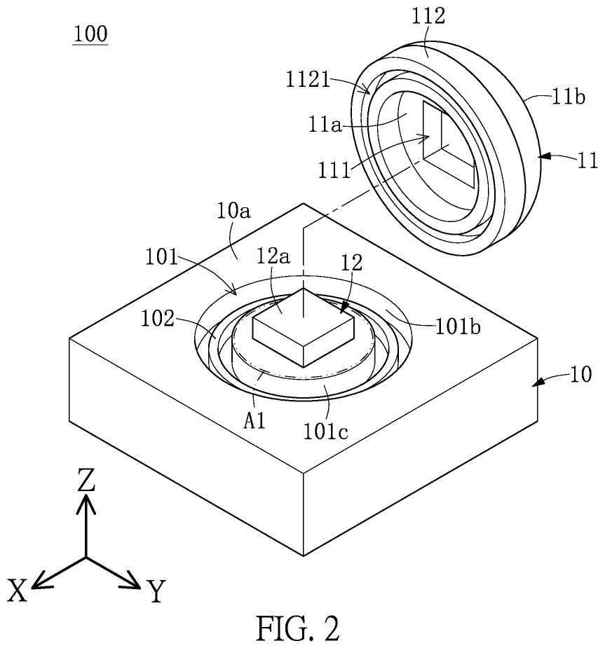

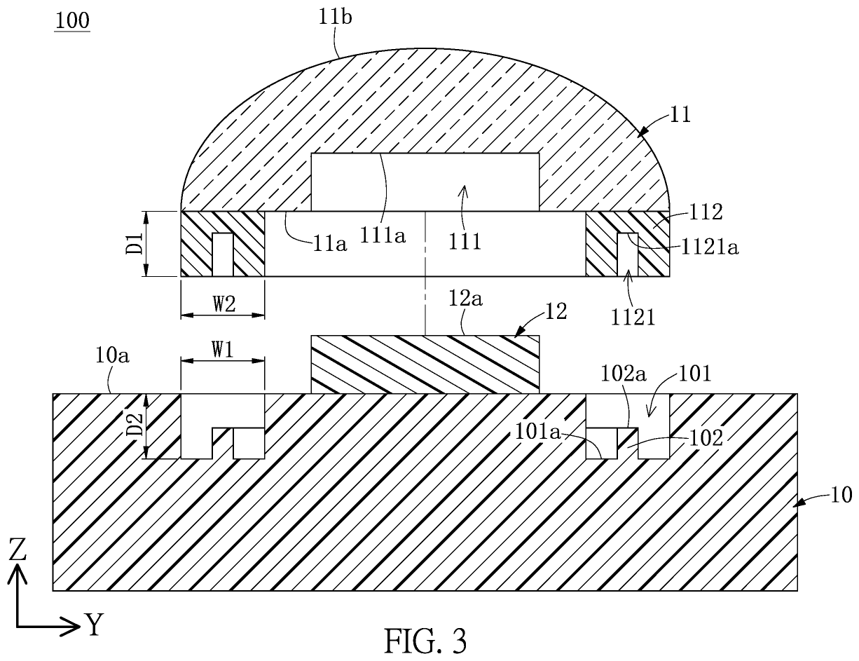

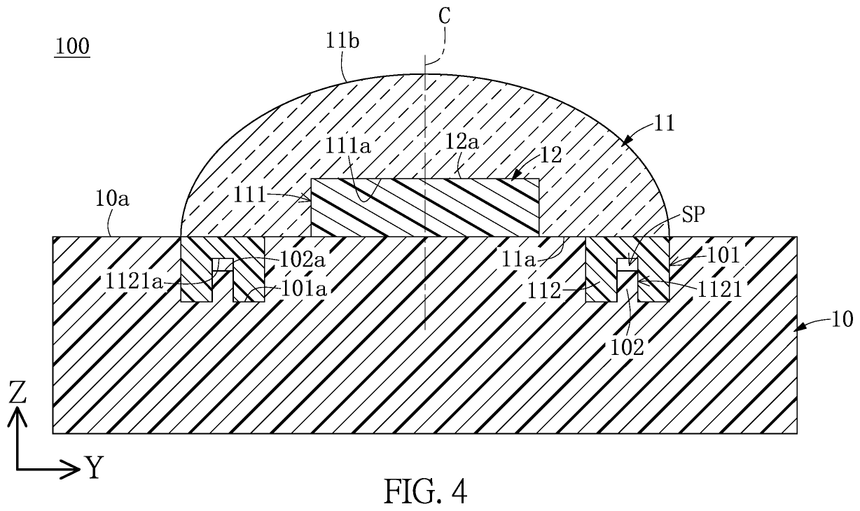

Referring to FIG. 1, FIG. 2, FIG. 3 and FIG. 4, FIG. 1 is a perspective view of a light-emitting unit of the present disclosure; FIG. 2 is a perspective exploded view of the light-emitting unit of the present disclosure; FIG. 3 is a sectional exploded view of the light-emitting unit of the present disclosure; FIG. 4 is a sectional assembled view of the light-emitting unit of the present disclosure. As shown in the figures, the light-emitting unit 100 at least includes a substrate 10, an optical lens 11, and a light-emitting chip 12.

As shown in FIG. 2 and FIG. 3, one side surface of the substrate 10 is defined as a supporting surface 10a, and the substrate 10 has a surrounding groove 101 that is recessed inwardly from the supporting surface 10a. The substrate 10 has a mount region Al is surroundingly defined by the surrounding groove 101 to be isolated. In the present embodiment, the surrounding groove 101 is in the shape of a circle, but is not limited thereto. Depending on requirements, the surrounding groove 101 may be in the shape of an ellipse or a rectangle.

The substrate 10 has a retaining structure 102 located in the surrounding groove 101, and the retaining structure 102 dose not protrude out of the surrounding groove 101, that is, the retaining structure 102 has a top end that is not higher than the supporting surface 10a. The retaining structure 102 is in the form of a loop, but is not limited thereto, and the shape thereof may be changed according to requirements. In practice, the retaining structure 102 may be integrally formed with the substrate 10. In one special application, the retaining structure 102 may also be formed in the surrounding groove 101 by secondary processing. There are two gaps between the retaining structure 102 and two opposite side walls 101b, 101c shown in FIG. 2 of the surrounding groove 101, respectively.

The optical lens 11 has a connection surface 11a and a light output surface 11b. The optical lens 11 has a concavity 111 that is recessed from one side of the connection surface 11a. The shape and volume of the concavity 111 can be changed according to the shape and size of the light-emitting chip 12, but is not limited thereto. The light output surface 11b of the optical lens 11 can be a hemispherical-like surface, and the optical lens 11 has a light-condensing function. In certain embodiments (not shown), the optical lens 11 is a square convex lens and has a shape that complements the shape of the substrate 10.

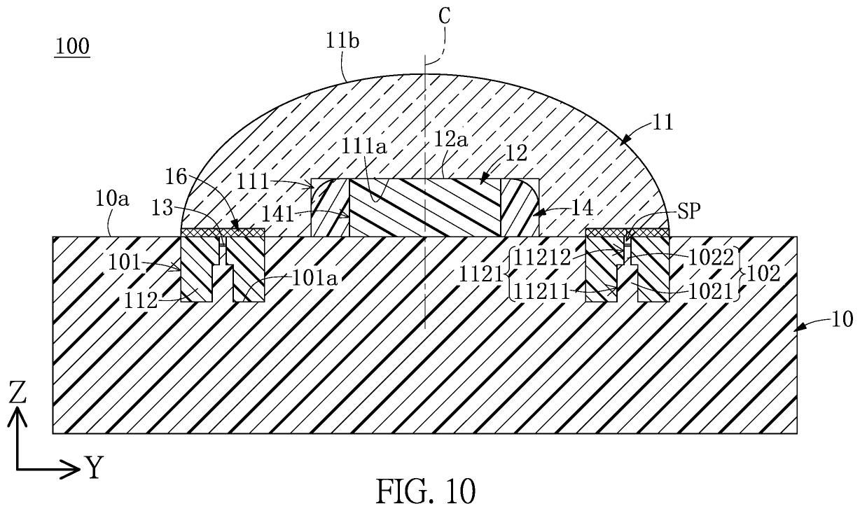

The optical lens 11 has an auxiliary retaining member 112 extending from the one side of the connection surface 11a. The auxiliary retaining member 112 has a ring shape that substantially complements the shape of the shape of the surrounding groove 101. In the present embodiment, the auxiliary retaining member 112 and the optical lens 11 are integrally formed with each other, but the present disclosure is not limited thereto. The auxiliary retaining member 112 and the optical lens 11 may not be integrally formed with each other , as shown in FIG. 10. The auxiliary retaining member 112 has a retaining groove 1121 that is recessed from one side thereof. The shape of the retaining groove 1121 substantially complements the shape of the retaining structure 102, and the can entirely accommodate the retaining structure 102.

Referring to FIG. 4, a sectional assembled view of the light-emitting unit of the present disclosure is shown. The optical lens 11 is disposed on the substrate 10, and a portion of the connection surface 11a abuts the supporting surface 10a of the substrate 10. The light-emitting chip 12 is disposed on the supporting surface 10a of the substrate 10 and is correspondingly located in the concavity 111 of the optical lens 11. The light beam emitted from the light-emitting chip 12 is projected outwardly through the optical lens 11. In certain embodiments, the light output surface 12a of the light-emitting chip 12 may abuts an end surface 111a of the concavity 111, as shown in FIG. 3. Accordingly, the emitted light beam of the light-emitting chip 12, which travels along the optical axis C of the optical lens 11, can directly enter the optical lens 11. Therefore, the light utilization rate of the light-emitting chip 12 can be improved, i.e., the emitted light beam of the light-emitting chip 12, which substantially travels along the optical axis C of the optical lens 11, can be sufficiently utilized.

The type of the light-emitting chip 12 may be changed according to requirements. For example, the light-emitting chip 12 may emit ultraviolet lights with a peak wavelength of 380 nm or less. In practice, a UV chip with a wavelength of 350 nm or a chip that emits colored lights or infrared lights can also be used. However, there is not limitation in the type of the light-emitting chip 12. In addition, in the present embodiment, the optical lens 11 can concentrate the light beam emitted from the light-emitting chip 12, so as to allow the light beam to travel toward the optical axis C of the optical lens 11. The optical lens 11 can be a convex lens. However, in the present disclosure, the type of the optical lens 11 can be changed according to requirements, and is not limited to the convex lens.

In certain embodiments, the volume of the concavity 111 is approximately equal to the size of the light-emitting chip 12, and the light-emitting chip 12 can be completely accommodated in the concavity 111. As shown in FIG. 4 of the present embodiment, the light output surface 12a of the light-emitting chip 12 is substantially attached to the end surface 111a of the concavity 111 and there is no gap between the light-emitting chip 12 and the end surface 111a of the concavity 111, but the present disclosure is not limited thereto. In practice, there may be a reserved gap between the light-emitting chip 12 and the end surface forming the concavity 111.

When the optical lens 11 is disposed on the substrate 10, the auxiliary retaining member 112 is correspondingly engaged in the surrounding groove 101 and the retaining structure 102 is correspondingly engaged in the retaining groove 1121, and the retaining structure 102 and the retaining groove 1121 are completely embedded in the substrate 10. That is, an end surface 1121a of the retaining groove 1121 is lower than the supporting of the substrate 10. In another embodiment, the end surface 1121a of the retaining groove 1121 may also be flush with the supporting surface 10a.

As described above, when the optical lens 11 is disposed on the substrate 10, the optical lens 11 and the substrate 10 can be fixedly connected to each other while the retaining structure 102 and the retaining groove 1121 are engaged with each other. That is, the optical lens 11 and the substrate 10 are fixed together by the retaining structure 102 and the retaining groove 1121.

In practice, adhesive(s) can be applied to appropriate positions of the optical lens 11 and the substrate 10 to assist in connecting the optical lens 11 to the substrate 10. For example, an adhesive (not shown) may be filled between the auxiliary retaining member 112 and the side wall of the surrounding groove 101, or filled between the retaining structure 102 and the side wall of the retaining groove 1121. Also, one adhesive is filled between the auxiliary retaining member 112 and the side wall of the surrounding groove 101 and another adhesive is filled between the retaining structure 102 and the side wall forming the retaining groove 1121. In specific embodiments, according to the position(s) of the adhesive(s), the volume of the surrounding groove 101 and/or the volume of the retaining groove 1121 may be slightly larger than the size of the auxiliary retaining member 112 and/or the size of the retaining structure 102, correspondingly.

As shown in FIG. 3, in specific embodiments, a ratio of the width W1 of the surrounding groove 101 to the width W2 of the auxiliary retaining member 112 can be between 1:0.95 and 1:1. If the width W2 of the auxiliary retaining member 112 is less than 0.95 times the width W1 of the surrounding groove 101, there may be an excessive gap between the surrounding groove 101 and the auxiliary retaining member 112, and this may negatively affect the connection strength between the surrounding groove 101 and the auxiliary retaining member 112.

In the embodiment, in which the optical lens 11 is fixedly disposed on the substrate 10 and an adhesive (not shown) is filled between the retaining structure 102 and the side wall of the retaining groove 1121 to fix the retaining structure 102 and the substrate 10 together, a reserved space SP is formed between the retaining structure 102 and the retaining groove 1121. The reserved space SP is used to accommodate the adhesive. In practical installation process, before the adhesive can be disposed on an end surface 102a of the remaining structure 102 away from the bottom of the surrounding groove 101, and subsequently the optical lens 11 is mounted on the substrate 10. After mounting the optical lens 11 is on the substrate 10, the adhesive would be disposed in the reserved space SP. After performing a relevant curing treatment on the adhesive, the adhesive can be cured to adhere the optical lens 11 to the substrate 10, thereby increasing the connection strength between the optical lens 11 and the substrate 10. In specific embodiments, the ratio of the width W1 of the surrounding groove 101 to the width W2 of the auxiliary retaining member 112 can be between 1:0.95 and 1:1, as shown in FIG. 3, such that the reserved space SP would have a sufficient volume to accommodate the adhesive.

In addition, when the adhesive filled between the retaining groove 1121 and the retaining structure 102 expands due to high ambient temperatures, at least one expansion portion of the adhesive would be accommodated in the reserved space SP. That is, the reserved space SP can also be used to accommodate an expansion portion of the adhesive. Therefore, in the presence of the reserved space SP, the connection strength between the optical lens 11 and the substrate 10 can be prevented from being negatively affected after the expansion of the adhesive.

It should be noted that, as shown in FIG. 4, since the surrounding groove 101 and the retaining groove 1121 both are located under the supporting surface 10a of the substrate 10 and the light-emitting chip 12 is disposed on the supporting surface 10a, the light beam emitted from the light-emitting chip 12 would not easily irradiate the adhesive filled in the surrounding groove 101 or the retaining groove 11121. Therefore, the service life of the adhesive can be significantly increased. In other words, if the adhesive is disposed at a position where it is easily irradiated by the light beam emitted from the light-emitting chip 12, the aging speed of the adhesive may be significantly increased, especially in the situation that the light-emitting chip 12 emits ultraviolet lights. If the adhesive is irradiated with ultraviolet lights for a long period of time, the aging speed would be significantly increased.

In addition, the surrounding groove 101 and the retaining groove 1121 are located under the supporting surface 10a of the substrate 10, such that the retaining structure 102 and the adhesive for adhering the optical lens 11 to the substrate 10 do not block or affect the outwardly projected light beam that is emitted from the light-emitting chip 12 and passes through the optical lens 11.

It should be noted that, in the light-emitting unit 100 of the present disclosure, the optical lens 11 and the light-emitting chip 12 can be disposed on a predetermined position of the substrate 10 by the designs of the surrounding groove 101, the retaining structure 102, and the retaining groove 1121. Accordingly, the light beam emitted from the light-emitting chip 12 can pass through the optical lens 11 to generate a desired lighting pattern. If the optical lens 11 and the light-emitting chip 12 are not disposed on the predetermined position of the substrate 10, the light-emitting unit 100 may not generate the desired lighting pattern.

Therefore, by the designs of the surrounding groove 101, the retaining structure 102, and the retaining groove 1121, the light-emitting unit 100 of the present disclosure can produce the desired lighting pattern while the optical lens 11 and the light-emitting chip 12 are disposed on the predetermined position of the substrate 10. In addition, the adhesive for adhering the optical lens 11 to the substrate 10 is not easily irradiated with the light beam emitted from the light-emitting chip 12, so that the adhesive has a longer service life.

The steps for manufacturing the light-emitting unit of the present disclosure as described above can include:

a substrate forming step: forming a surrounding groove and a retaining structure on the substrate, wherein the surrounding groove is recessed from the supporting surface, the retaining structure is located in the surrounding groove and does not protrude out of the supporting surface, and the surrounding groove isolatingly defines a mount region on the supporting surface and surrounds the mount region;

a light-emitting chip fixing step: fixedly disposing the light-emitting chip in the mount region, wherein the light-emitting chip is electrically connected to the substrate; and

an optical lens fixing step of: engaging an auxiliary retaining member of the optical lens in the surrounding groove while correspondingly engaging the retaining structure in the retaining groove of the auxiliary retaining member to fix the optical lens on the supporting surface of the substrate, wherein the light-emitting chip is disposed in the concavity of the optical lens, and the light beam emitted from the light-emitting chip is projected outwardly through the optical lens, and a reserved space is formed between the retaining structure and the retaining groove.

The details of the components as described in the above steps can be referred to in the foregoing embodiments, and will not be reiterated herein. According to particular requirements, a dispensing step can be conducted before the optical lens fixing step and includes placing the adhesive on the end surface of the remaining structure away from the bottom of the surrounding groove. In the optical lens fixing step, the resulting adhesive is correspondingly located in the reserved space. A curing step can be conducted after the optical lens fixing step and includes irradiating the adhesive with a predetermined light beam so as to cure the adhesive.

### Second Embodiment

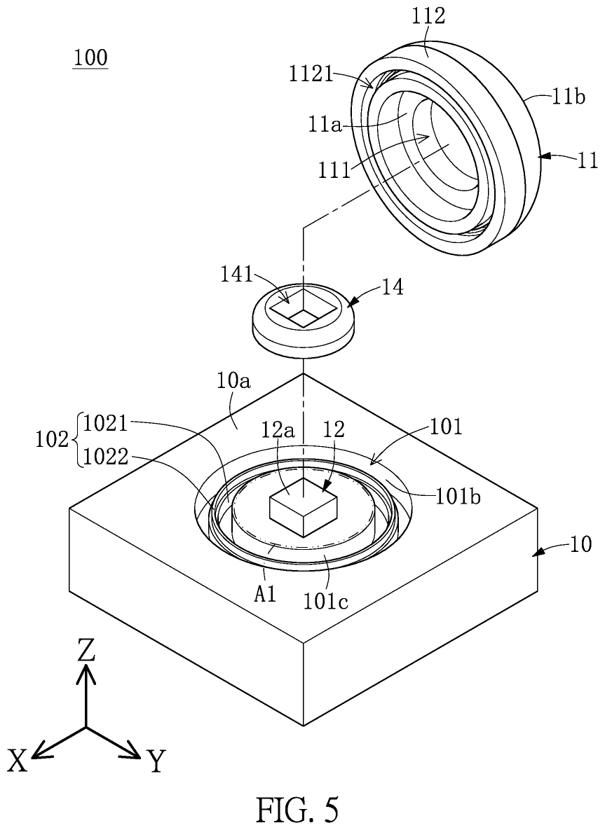

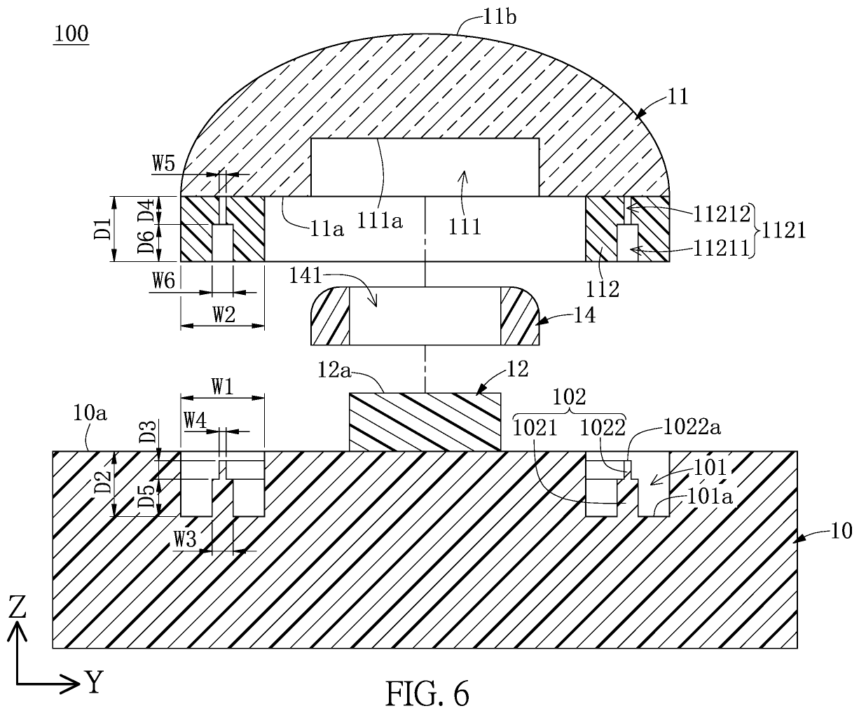

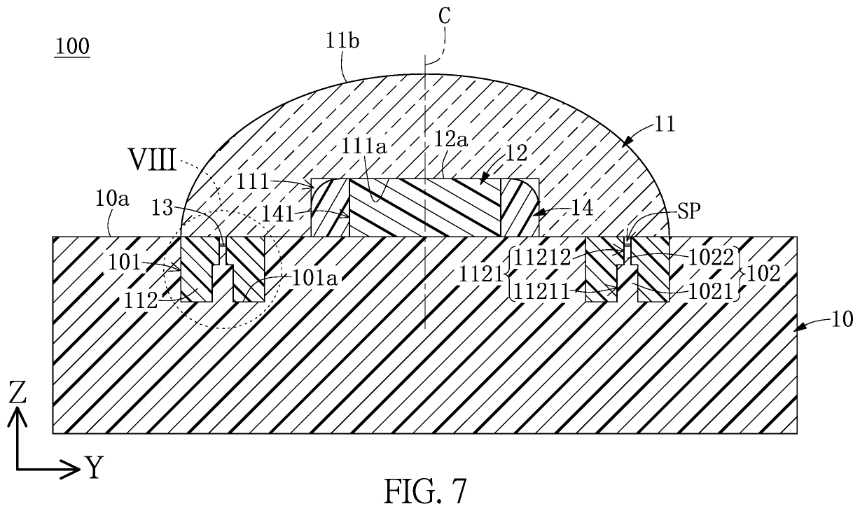

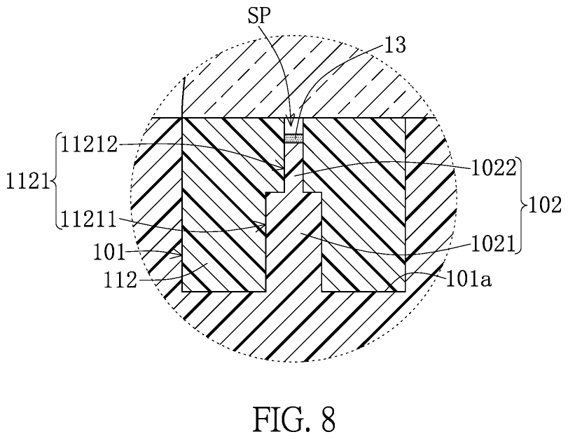

Referring to FIG. 5, FIG. 6, FIG. 7 and FIG. 8, schematic views of a light-emitting unit according the second embodiment of the present disclosure are shown. As shown in the figures, the main differences between the present embodiment and the foregoing embodiments is that the light-emitting unit 100 further includes an auxiliary lens 14 and the retaining structure 102 has a lower end portion 1021 and an upper end portion 1022. In the following description, only the auxiliary lens 14, the lower end portion 1021, and the upper end portion 1022 will be described in detail. The details of the remaining components can be referred to in the foregoing embodiment, and will not be reiterated herein.

It should be particularly emphasized that although the figures of the present embodiment show that the light-emitting unit 100 has the auxiliary lens 14 and the retaining structure 102 has the lower end portion 1021 and the upper end portion 1022, the implementation of the light-emitting unit 100 is not limited thereto. In different embodiments, the light-emitting unit 100 may have the auxiliary lens 14, but not have the lower end portion 1021 and the upper end portion 1022. Also, the light-emitting unit 100 may have the lower end portion 1021 and the upper end portion 1022, but not have the auxiliary lens 14.

The auxiliary lens 14 is disposed on the supporting surface 10a of the substrate 10 and located in the mount region Al. That is, the surrounding groove 101 surrounds the auxiliary lens 14. The auxiliary lens 14 has an accommodating groove 141 that is recessed from one side thereof for arranging the light-emitting chip 12. In the present embodiment, the accommodating groove 141 passes through the auxiliary lens 14, but is not limited thereto. According to different applications, the accommodating groove 141 does not pass through the auxiliary lens 14.

The auxiliary lens 14 can cooperate with the optical lens 11 so that the light-emitting unit 100 can generate different predetermined lighting patterns. That is to say, the lighting pattern of the light-emitting unit 100 of the present embodiment can be changed by the optical lens 11 and/or the auxiliary lens 14.

Furthermore, the auxiliary lens 14 can also be used to control the optical path between the light-emitting chip 12 and the optical lens 11, so that the light beam emitted from the light-emitting chip 12 can be concentrated toward the optical axis C of the optical lens 11. For example, the lateral light beam emitted from the light-emitting chip 12 can be guided by the auxiliary lens 14 to travel close to the optical lens 11. Accordingly, the light beam emitted from the light-emitting chip 12 can be concentrated toward the optical axis C of the optical lens 11. Therefore, the luminous flux of the lateral light beam (i.e., light beam substantially travelling along the +Y-axis or −Y-axis direction shown in FIG. 7) emitted from the light-emitting chip 12 is greater than that of the forward light beam (i.e., light beam substantially travelling along the +Z-axis or −Z-axis direction shown in FIG. 7) emitted from the light-emitting chip 12.

In the embodiment in which the accommodating groove 141 of the auxiliary lens 14 passes through the auxiliary lens 14, the light output surface 12a of the light-emitting chip 12 can contact the end surface 111a of the concavity 111, as shown in FIG. 6. Thus, the light beam emitted from the light-emitting chip 12 substantially and travelling along the optical axis C of the optical lens 11 can directly enter the optical lens 11 without passing through the auxiliary lens 14. Therefore, the emitted light beam of the light-emitting chip 12, especially the emitted light beam substantially travelling along the optical axis C of the optical lens 11, can be sufficiently utilized so as to increase the light utilization rate.

In specific embodiments, the auxiliary lens 14 and the optical lens 11 may be made of the same material and have substantially the same refractive index, but the present disclosure is not limited thereto. The auxiliary lens 14 and the optical lens 11 may be made of different materials and have different refractive indexes. The auxiliary lens 14 and the optical lens 11 having different refractive indexes may cooperate with the contours of the auxiliary lens 14 and the concavity 111, and thus the light-emitting unit 100 generates a predetermined lighting pattern.

As shown in FIG. 6, in specific embodiments, the ratio of the width W1 of the surrounding groove 101 to the width W2 of the auxiliary retaining member 112 may be between 1:0.95 and 1:1. In the embodiment in which the width W2 of the auxiliary retaining member 112 is less than 0.95 times the width W1 of the surrounding groove 101, there may be an excessive gap between the surrounding groove 101 and the auxiliary retaining member 112, and this may negatively affect the connection strength between the surrounding groove 101 and the auxiliary retaining member 112.

In specific embodiments, the ratio of the depth D2 of the surrounding groove 101 to the length D1 of the auxiliary retaining member 112 may be between 1:0.5 and 1:0.95. During the manufacturing process, if the length D1 of the auxiliary retaining member 112 is less than 0.5 times the depth D2 of the surrounding groove 101, the depth of the second groove section 11212 may be too shallow and thus cause a difficulty in the manufacture of the optical lens, while the retaining groove 1121 is located below the supporting surface 10a for fixing the optical lens 11 and the substrate 10 together.

As shown in FIG. 5 and FIG. 6, the lower end portion 1021 of the retaining structure 102 may extend from the bottom 101a of the surrounding groove 101 and toward the supporting surface 10a, and the upper end portion 1022 may extend from one end of the lower end portion 1021 away from the bottom 101a of the surrounding groove 101 and toward the supporting surface 10a. The maximum width W3 of the lower end portion 1021 is smaller than the width W1 of the surrounding groove 101, and the maximum width W4 of the upper end portion 1022 is smaller than the minimum width W3 of the lower end portion 1021. In the present embodiment, a stepped structure is jointly formed by the lower end portion 1021 and the upper end portion 1022. The retaining groove 1121 has a first groove section 11211 and a second groove section 11212. The first groove section 11211 can accommodate the lower end portion 1021, and the second groove section 11212 can accommodate the upper end portion 1022. In the present embodiment, the lower end portion 1021 and the upper end portion 1022 are respectively a rectangular column structure, but the present disclosure is not limited thereto. In different embodiments, the lower end portion 1021 and the upper end portion 1022 each may be in the shape of a truncated cone or a truncated pyramid.

As shown in FIG. 7 and FIG. 8, when the optical lens 11 is disposed on the substrate 10, the lower end portion 1021 is correspondingly disposed in the first groove section 11211 and the upper end portion 1022 is correspondingly disposed in the second groove section 11212, and the reserved space SP is formed between the second groove section 11212 and the upper end portion 1022. In the process of mounting the optical lens 11 on the substrate 10, the adhesive may be disposed on the end surface 1022a as shown in FIG. 6 of the upper end portion 1022 away from the upper end portion 1022, and then the optical lens 11 is disposed on the substrate 10. Accordingly, the adhesive is correspondingly located in the reserved space SP. After that, a relevant curing treatment is performed on the adhesive 13 so as to cure the adhesive 13. Therefore, the connection strength between the optical lens 11 and the substrate 10 can be enhanced by the cured adhesive 13. It should be noted that, the light-emitting unit 100 may not be provided with the adhesive 13, and the optical lens 11 and the substrate 10 are fixed to each other only by the retaining structure 102 and the retaining groove 1121.

As shown in FIG. 6, in specific embodiments, the ratio of the height D3 of the upper end portion 1022 to the depth D4 of the second groove section 11212 may be between 0.33:1 and 0.5:1. Accordingly, the reserved space SP has enough space to accommodate the adhesive 13.

In the embodiment in which the height D3 of the upper end portion 1022 is 0.5 times or more the depth D4 of the second groove section 11212, the reserved space SP does not have enough space for accommodating thermally expanded adhesive 13 and thus the adhesive 13 may press against the side wall of the retaining groove 1121 or the retaining structure 102, and this may affect the lighting pattern generated by the light-emitting unit 100.

In a the embodiment in which the height D3 of the upper end portion 1022 is less than 0.33 times the depth D4 of the second groove section 11212, in the process of mounting the optical lens 11 on the substrate 10, the adhesive disposed on the end surface of the upper end portion 1022 may overflow to a space between the lower end portion 1021 and the side wall of the retaining groove 1121 since the height D3 of the upper end portion 1022 is too short. Thus, the lighting pattern generated by the light-emitting unit 100 may be affected by the cured adhesive.

In specific embodiments, the ratio of the width W4 of the upper end portion 1022 to the width W5 of the second groove section 11212 may be between 0.98:1 and 1:1. In the embodiment in which the width W4 of the upper end portion 1022 is less than 0.98 times the width W5 of the second groove section 11212, the alignment accuracy between the upper end portion 1022 and the second groove section 11212 may be affected, and this may affect the light shape generated by the light-emitting unit 100.

In specific embodiments, the ratio of the height D5 of the lower end portion 1021 to the depth D6 of the first groove section 11211 may be between 1:0.9 and 1:0.95. In the embodiment in which the height D5 of the lower end portion 1021 is less than 0.9 times the depth D6 of the first groove section 11211, when the optical lens 11 is mounted on the substrate 10, there may be an excessive gap between the lower end portion 1021 and the side wall of the first groove section 11211, and this may negatively affect the connection strength between the optical lens 11 and the substrate 10.

In specific embodiments, the ratio of the width W3 of the lower end portion 1021 to the width W6 of the first groove section 11211 may be between 0.95:1 and 1:1. In the embodiment in which the width W3 of the lower end portion 1021 is less than 0.95 times the width W6 of the first groove section 11211, in the process of mounting the optical lens 11 on the substrate 10, the adhesive disposed on the end surface of the upper end portion 1022 may overflow to a space between the lower end portion 1021 and the side wall of the retaining groove 1121. Thus, the lighting pattern generated by the light-emitting unit 100 may be affected by the cured adhesive.

By the designs of the lower end portion 1021 and the upper end portion 1022 as described above, the optical lens 11 can be correctly mounted on the predetermined position of the substrate 10, such that the lighting pattern generated by the light-emitting unit 100 precisely controlled.

The manufacturing steps of the above embodiment may include:

a substrate forming step: forming a surrounding groove and a retaining on the structure, wherein the surrounding groove is recessed from the supporting surface of the substrate; the retaining structure is located in the surrounding groove and does not protrude out of the supporting surface; the surrounding groove isolatingly defines a mount region on the supporting surface and surrounds the mount region; the retaining structure has a lower end portion and an upper end portion, the lower end portion extends outwardly from the bottom of the surrounding groove, and the upper end portion extends from the lower end portion and along a direction away from the bottom of the surrounding groove;

a light-emitting chip fixing step: fixedly disposing the light-emitting chip in the mount region, wherein the light-emitting chip is electrically connected to the substrate; and

an optical lens fixing step: engaging an auxiliary retaining member of the optical lens in the surrounding groove while correspondingly engaging the retaining structure in the retaining groove of the auxiliary retaining member to fix the optical lens on the supporting surface of the substrate; the light-emitting chip is disposed in the concavity of the optical lens, and the light beam emitted from the light-emitting chip is projected outwardly through the optical lens; the retaining groove has a first groove section and a second groove section, the lower end portion and the upper end portion are respectively disposed in the first groove section and the second groove section, and a reserved space is formed between the upper end portion and the second groove section.

The details of the components as described in the above steps can be referred to in the foregoing embodiments, and will not be reiterated herein. According to particular requirements, a dispensing step can be conducted before the optical lens fixing step, and includes placing the adhesive on the end surface of the upper end portion away from the lower end portion. In the optical lens fixing step, the resulting adhesive is correspondingly located in the reserved space. A curing step can be conducted after the optical lens fixing step, and includes irradiating the adhesive with a predetermined light beam so as to cure the adhesive.

### Third Embodiment

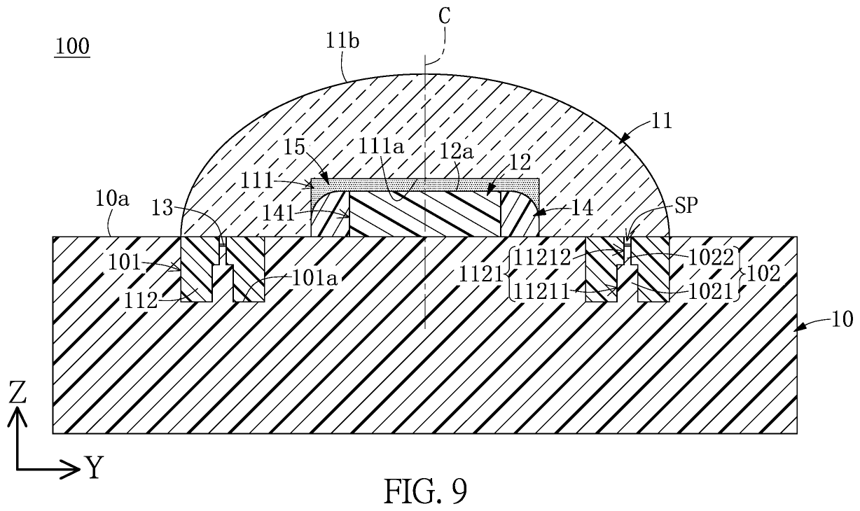

Referring to FIG. 9, a sectional view of the light-emitting unit according to a third embodiment of the present disclosure is shown. As shown in the figure, the main differences between the present embodiment and the foregoing embodiments is that an accommodating space is formed between the auxiliary lens 14 and the end surface 111a of concavity 111, the accommodating space is filled with a light-transmitting adhesive 15, and the auxiliary lens 14 is connected to the end surface 111a of the concavity 111 via the light-transmitting adhesive 15. The refractive index of the light-transmitting adhesive 15 may be the same as the refractive index of the optical lens 11 or the refractive index of the auxiliary lens 14.

It should be noted that, in different embodiments, the light-transmitting adhesive 15 may also be filled between annular side walls of the auxiliary lens 14 and the concavity 111. That is, the auxiliary lens 14 is connected to the optical lens 11 by the light-transmitting adhesive 15 between the annular side walls of the auxiliary lens 14 and the concavity 111. The accommodation space between the auxiliary lens 14 and the end surface 111a of the concavity 111 is used to accommodate a portion of the light-transmitting adhesive 15 that is squeezed out by the compression of the auxiliary lens 14 and the optical lens 11.

### Fourth Embodiment

Referring to FIG. 10, a sectional view of a light-emitting unit according to a fourth embodiment of the present disclosure is shown. As shown in the figure, the main differences between the embodiment and the foregoing embodiment is that the auxiliary retaining member 112 and the optical lens 11 are not integrally formed with each other, and a light-shading member 16 is disposed between the auxiliary retaining member 112 and the optical lens 11. The light-shading member 16 can block the light beam emitted from the light-emitting chip 12 from entering the auxiliary retaining member 112. Accordingly, the adhesive 13 located in the surrounding groove 101 or the retaining groove 11121 will not be irradiated with the light beam emitted by the light-emitting chip 12, and therefore the service life of the adhesive 13 can be extended. In another embodiment, the auxiliary retaining member 112 and the optical lens 11 do not have a light-shading member 16 therebetween, while the auxiliary retaining member 112 is an opaque structure, such that the service life of the adhesive 13 can be improved. In addition, a reflecting member may be used in place of the light-shading member 16. Accordingly, the light beam entering the retaining structure 102 can be reflected back into the optical lens 11. The reflecting member may be, for example, a layered structure formed by coating between the retaining structure 102 and the optical lens 11, but is not limited thereto.

### Fifth Embodiment

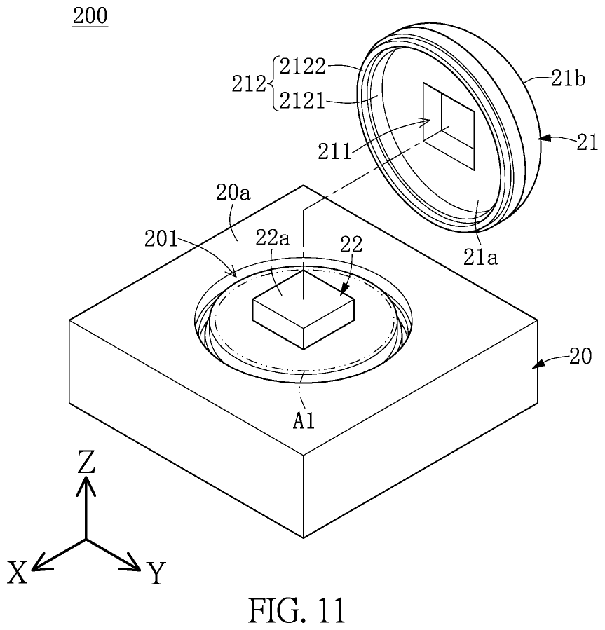

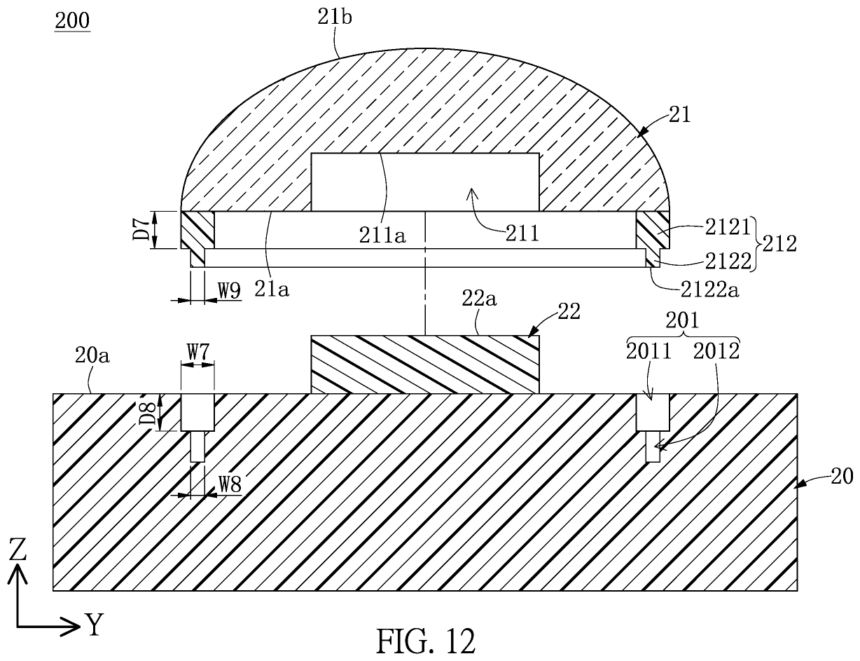

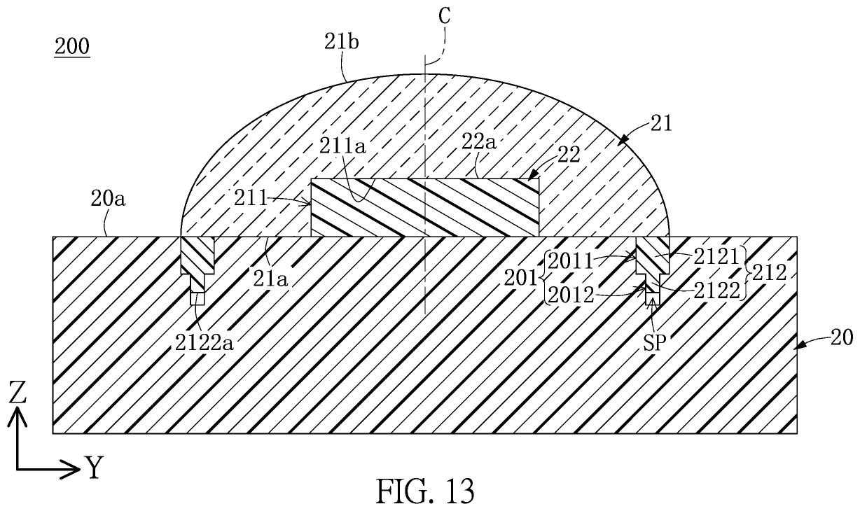

Referring to FIG. 11, FIG. 12 and FIG. 13, FIG. 11, schematic views of a light-emitting unit according a fifth embodiment of the present disclosure are shown. As shown in the figures, the light-emitting unit 200 includes a substrate 20, an optical lens 21, and a light-emitting chip 22.

One side of the substrate 20 is defined as a supporting surface 20a. The substrate 20 has a retaining groove 201 that is recessed from the supporting surface 20a. The retaining groove 201 is in the form of a loop, and the substrate 20 has a mount region Al that is surroundingly defined by the retaining groove 201 to be isolated. The retaining groove 201 surrounds the mount region Al. In the present embodiment, the retaining groove 201 has a circular ring shape, but is not limited thereto. According to requirements, the retaining groove 201 may have an elliptical ring shape or a rectangular ring shape.

The optical lens 21 has a connection surface 21a and a light output surface 21b. The optical lens 21 has a concavity 211 that is recessed from one side of the connection surface 21a. The shape and volume of the concavity 211 can be designed according to the shape and size of the light-emitting chip 22, and is not limited herein. The light output surface 21b of the optical lens 21 can be similar to a hemispherical-like surface, and the optical lens 21 has a light-condensing function of spotting light.

The retaining structure 212 has a lower end portion 2121 and an upper end portion 2122. The lower end portion 2121 extends from the connection surface 21a of the optical lens 21, and the upper end portion 2122 extends from the lower end portion 2121 and away from the connection surface 21a. The width of the upper end portion 2122 is smaller than the width of the lower end portion 2121. The lower end portion 2121 and the upper end portion 2122 respectively have a circular column shape. However, the geometric shape and the size of the lower end portion 2121 and the upper end portion 2122 are not limited to those as shown in the figures, and may be changed according to requirements. In different applications, the lower end portion 2121 and the upper end portion 2122 each may be in the form of an elliptical ring column or a square ring column. In the present embodiment, the retaining structure 212 and the optical lens 21 are integrally formed with each other, but the present disclosure is not limited thereto. In different applications, the retaining structure 212 may not be integrally formed with the optical lens 21.

As shown in FIG. 11 and FIG. 12, the retaining groove 201 has a first groove section 2011 and a second groove section 2012, the width W7 of the first groove section 2011 is greater than the width W8 of the second groove section 2012. The first groove section 2011 is used to accommodate the lower end portion 2121, and the second groove section 2012 is used to accommodate the upper end portion 2122. The first groove section 2011 and the second groove section 2012 are respectively annular, but the present disclosure is not limited thereto. In different applications, the first groove section 2011 and the second groove section 2012 may also be elliptical rings, square rings, and the like, respectively.

As shown in FIG. 13, the optical lens 21 is disposed on the substrate 20, and a portion of the connection surface 21a abuts against the supporting surface 20a of the substrate 20, as shown in FIG. 12. The light-emitting chip 22 is disposed on the supporting surface 20a of the substrate 20. The light-emitting chip 22 is located in the concavity 211 of the optical lens 21, and the light beam emitted from the light-emitting chip 22 is projected outwardly through the optical lens 21. The light output surface 22a of the light-emitting chip 22 abuts against an end surface 211a of the concavity 211, as shown in FIG. 12. Accordingly, the light beam emitted from the light-emitting chip 22, which travels along the optical axis C of the optical lens 21, can directly enter the optical lens 21, so as to increase the light utilization of the light-emitting chip 22. Particularly the light beam substantially travelling along the optical axis C of the optical lens 21 can be sufficiently utilized. The type of the light-emitting chip 22 may be changed according to requirements. For example, the light-emitting chip 22 may emit ultraviolet lights with a wavelength peak between 350 nm and 370 nm. In the present embodiment, the optical lens 21 can concentrate the light beam emitted from the light-emitting chip 22 to the optical axis C of the optical lens 21, and the optical lens 21 can be a convex lens. However, the type of the optical lens 21 can be changed according to requirements, and is not limited to the convex lens.

The volume of the concavity 211 is substantially equal to the size of the light-emitting chip 22, and the light-emitting chip 22 can be completely accommodated in the concavity 211. In the present embodiment, as shown in FIG. 12, the light output surface 22a of the light-emitting chip 22 substantially abuts against the end surface 211a of the concavity 211, and there is no gap between the light-emitting chip 22 and the end surface 211a of the concavity 211, but the present disclosure is not limited thereto. In practice, a reserved gap may be formed between the light-emitting chip 22 and the end surface 211a forming the concavity 211.

The retaining structure 212 is correspondingly engaged in the retaining groove 201, the lower end portion 2121 is correspondingly placed in the first groove section 2011, and the upper end portion 2122 is correspondingly placed in the second groove section 2012. A reserved space SP is formed between the end surface 2122a of the upper end portion 2122 and a portion of the side wall of the second groove section 2012. When the optical lens 21 is disposed on the substrate 20, the retaining structure 212 is completely engaged in the retaining groove 201, and is not exposed from the supporting surface 20a.

By the cooperation of the lower end portion 2121, the upper end portion 2122, the first groove section 2011, and the second groove section 2012, the optical lens 21 can be correctly mounted on the predetermined position of the substrate 20. Therefore, the light-emitting unit 200 can produce a desired lighting pattern.

In various embodiments, the adhesive may be filled in the reserved space SP to fix the optical lens 21 to the substrate 20, so that the optical lens 21 and the substrate 20 can be firmly fixed to each other.

It should be noted that in the embodiment in which the retaining structure 212 and the optical lens 21 are not integrally formed with each other, the retaining structure 212 may be an opaque structure, for example, a structure made of an opaque material. Thus, the light beam emitted from the light-emitting chip 22 will not easily enter the retaining structure 212 by the reflection or refraction of the optical lens 21 to irradiate the adhesive disposed in the reserved space SP, and this may cause a shorter service life of the adhesive.

In the embodiment in which the retaining structure 212 and the optical lens 21 are not integrally formed, a light-shading member may be disposed between the retaining structure 212 and the optical lens 21, thereby completely blocking the light beam from entering the retaining structure 212. In addition, a reflecting member can be used in place of the light-shading member for reflecting the light beam entering the retaining structure 212 back into the optical lens 21. For example, the reflecting member may be a layered structure formed by coating between the retaining structure 212 and the optical lens 21, but the present disclosure is not limited thereto.

As shown in FIG. 12, in specific embodiments, the ratio of the length of the upper end portion 2122 to the depth of the second groove section 2012 may be between 0.33:1 and 0.5:1. Accordingly, the prepared space SP has enough space to accommodate the adhesive 13.

In a particular implementation, the ratio of the width W9 of the upper end portion 2122 to the width W8 of the second groove section 2012 may be between 0.98:1 and 1:1. In the embodiment in which the width W9 of the upper end portion 2122 is less than 0.98 times the width W8 of the second groove section 2012, the alignment accuracy between the upper end portion 2122 and the second groove section 2012 may be affected, and this may affect the lighting pattern generated by the light-emitting unit 200.

In specific embodiments, the ratio of the height D7 of the lower end portion 2121 to the depth D8 of the first groove section 2011 may be between 1:0.9 and 1:0.95. In the embodiment in which the height D7 of the lower end portion 2121 is less than 0.9 times the depth D8 of the first groove section 2011, when the optical lens 21 is mounted on the substrate 20, there may be an excessive gap between the lower end portion 2121 and the side wall of the first groove section 2011, and this may affect the strength of the connection between the optical lens 21 and the substrate 20.

In specific embodiments, the ratio of the width of the lower end portion 2121 to the width of the first groove section 2011 may be between 0.95:1 and 1:1.

### Sixth Embodiment

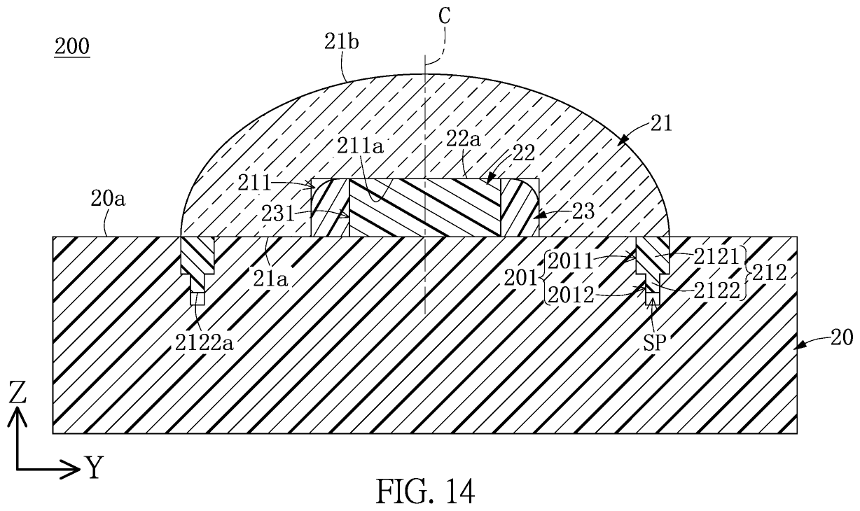

Referring to FIG. 14, a schematic view of a light-emitting unit according to a sixth embodiment of the present disclosure is shown. As shown in the figure, the main differences between this embodiment and the foregoing embodiment is that the light-emitting unit 200 can also have an auxiliary lens 23, the auxiliary lens 23 has an accommodating groove 231, and the accommodating groove 231 passes through the auxiliary lens 23. The auxiliary lens 23 is disposed on the supporting surface 20a of the substrate 20, the auxiliary lens 23 is located in the concavity 211 of the optical lens 21, and the light-emitting chip 22 is located in the accommodating groove 231. In the embodiment, the accommodating groove 231 passes through the auxiliary lens 23, but the present disclosure is not limited thereto. In different applications, the accommodating groove 231 does not pass through the auxiliary lens 23.

The auxiliary lens 23 is used to control the optical path of the light beam emitted from the light-emitting chip. For example, the light beams emitted from the light-emitting chip 22 may include forward light beam(s) and lateral light beam(s), and the luminous flux of the lateral light bean is greater than that of the forward light beam. The auxiliary lens 23 can be used to convert the lateral light emitted by the light-emitting chip 22 into the forward light, thereby effectively reducing the light-emitting angle of the light-emitting unit 200. Accordingly, the light beam emitted from the light-emitting unit 200 can be concentrated to the optical axis C of the optical lens 21. That is, the auxiliary lens 23 can cooperate with the optical lens 21 to guide the light beam emitted by the light-emitting chip 22, so that the light-emitting unit 200 can generate a desired lighting pattern. In actual implementation, the refractive index of the auxiliary lens 23 may be the same as the refractive index of the optical lens 21, so that the light utilization rate of the auxiliary lens 23 can be improved.

In specific embodiments, the auxiliary lens 23 and the optical lens 21 may be made of the same material, and the auxiliary lens 23 and the optical lens 21 may have substantially the same refractive index, but the present disclosure is not limited thereto. The auxiliary lens 23 and the optical lens 21 may also be made of different materials, and have different refractive indexes. The auxiliary lens 23 and the optical lens 21 having different refractive indexes may cooperate with the contours of the auxiliary lens 23 and the concavity 211, and thus the light-emitting unit 200 generates a predetermined lighting pattern.

In different embodiments, the auxiliary lens 23 and the end surface 211a of the concavity 211 may be filled with a light-transmitting adhesive and the auxiliary lens 23 may be fixed to an optical lens 21 by the light-transmitting adhesive. The refractive index of the light-transmitting adhesive may be the same as that of the auxiliary lens 23 and the optical lens 21, thereby improving the beam efficiency of the light emitted by the light-emitting chip 22.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A light-emitting unit, comprising:
a substrate having a surrounding groove and a retaining structure located in the surrounding groove;
an optical lens disposed on the substrate and having a concavity and an auxiliary retaining member, the auxiliary retaining member having a retaining groove, wherein the auxiliary retaining member is engaged in the surrounding groove, and the retaining structure is engaged in the retaining groove; and
a light-emitting chip disposed on the substrate and located in the concavity;
wherein a reserved space is formed between the retaining structure and the retaining groove.

2. The light-emitting unit according to claim 1, wherein the light-emitting chip is disposed on a supporting surface of the substrate, and a top surface of the retaining groove is flush with or lower than the supporting surface.

3. The light-emitting unit according to claim 1, wherein the light-emitting unit further includes an auxiliary lens disposed on the substrate and located in the concavity; the auxiliary lens has an accommodating groove, and the light-emitting chip is located in the accommodating groove.

4. The light-emitting unit according to claim 1, wherein the light-emitting unit further includes a cured adhesive to adhere the retaining structure to a wall surface of the retaining groove, and a portion of the cured adhesive is accommodated in the reserved space.

5. The light-emitting unit according to claim 1, wherein the auxiliary retaining member and the optical lens are integrally formed with each other.

6. The light-emitting unit according to claim 1, wherein the retaining structure has a lower end portion and an upper end portion, the lower end portion is formed at a bottom of the surrounding groove, and the upper end portion is formed at one end of the lower end portion away from the bottom of the surrounding groove.

7. The light-emitting unit according to claim 6, wherein a maximum width of the lower end portion is smaller than a width of the surrounding groove, and a maximum width of the upper end portion is smaller than a minimum width of the lower end portion.

8. The light-emitting unit according to claim 6, wherein the retaining groove has a first groove section and a second groove section, the lower end portion is accommodated in the first groove section, and the upper end portion is accommodated in the second groove section.

9. The light-emitting unit according to claim 8, wherein the reserved space is formed between the second groove section and the upper end portion.

10. The light-emitting unit according to claim 1, wherein a ratio of a width of the surrounding groove to a width of the auxiliary retaining element is between 1:0.95 and 1:1.

11. The light-emitting unit according to claim 1, wherein a ratio of a depth of the surrounding groove to a length of the auxiliary retaining element is between 1:0.5 and 1:0.95.
